(19) United States
(12) Patent Application Publication
(10) Pub. No.: US 2008/0242091 A1
(43) Pub. Date: Oct. 2, 2008

(54) METAL-POLISHING LIQUID AND POLISHING METHOD

(75) Inventors: Tomoo KATO, Haibara-gun (JP); Takamitsu TOMIGA, Haibara-gun (JP); Sumi TAKAMIYA, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/043,729

(22) Filed: Mar. 6, 2008

(30) Foreign Application Priority Data
Mar. 29, 2007 (JP) 2007-088686

(51) Int. Cl. H01L 21/302; C09K 13/00

(52) U.S. Cl. 438/693; 252/79.1; 257/E21.214

(57) ABSTRACT

A metal-polishing liquid used for chemical and mechanical polishing of copper wiring in a semiconductor device, the metal-polishing liquid comprising: (a) a tetrazole compound having a substituent in the 5-position; (b) a tetrazole compound not substituted in the 5-position; (c) abrasive grains; and (d) an oxidizing agent.

### CROSS-REFERENCE TO RELATED APPLICATION

This application claims priority under 35 USC 119 from Japanese Patent Application No. 2007-088686, the disclosure of which is incorporated by reference herein.

### BACKGROUND

1. Technical Field

The present invention relates to a manufacture of semiconductor devices and more particularly to a metal-polishing liquid and a method for chemical and mechanical flattening of a metal which are employed in a wiring process for semiconductor devices.

2. Related Art

Recently, in the development of semiconductor devices typified by semiconductor integrated circuits (hereinafter, appropriately referred to as “LSI”), in order to achieve smaller size and higher speed, higher densification and higher integration by miniaturization of wirings and lamination are in demand. As a technique for this, various techniques such as chemical mechanical polishing (hereinafter, appropriately referred to as “CMP”) are in use. The CMP is a process that is used to polish metal thin films used in insulating thin films (SiO₂) and wirings in the production of semiconductor devices to remove superfluous metal thin films when a substrate is smoothed and wirings are formed (see, for instance, U.S. Pat. No. 4,944,836).

The metal-polishing liquid used in the CMP generally includes abrasive grains (such as alumina) and an oxidant (such as hydrogen peroxide). The mechanism of the polishing by means of the CMP is considered to be that the oxidant oxidizes a metal surface and a film of the oxide is removed by the abrasive grains to carry out polishing (see, for instance, Journal of Electrochemical Society, Vol. 138(11), pages 3460 to 3464 (1991)).

However, when the CMP is applied by use of the metal-polishing liquid containing such solid abrasive grains, in some cases, polishing scratches, a phenomenon where an entire polishing surface is polished more than necessary (thinning), a phenomenon where a polished metal surface is not planar, that is, only a center portion is polished deeper to form a dish-like concave (dishing), or a phenomenon where an insulating material between metal wirings is polished more than necessary and a plurality of wiring metal surfaces forms dish-like concaves (erosion) may be caused. Furthermore, when the metal-polishing liquid containing solid abrasive grains is used, in a cleaning process that is usually applied to remove the polishing liquid remaining on a polished semiconductor surface, the cleaning process becomes complicated and, furthermore, in order to dispose of the liquid after the washing (waste liquid), the solid abrasive grains have to be sedimented and separated; accordingly, there is a problem from the viewpoint of cost.

As a means to overcome such problems for instance, a metal surface polishing process where a polishing liquid that does not contain abrasive grains and dry etching are combined is disclosed (see, for instance, Journal of Electrochemical Society, Vol. 147 (10), pages 3907 to 3913 (2000)). Furthermore, a metal-polishing liquid that is made of hydrogen peroxide/malic acid/benzotriazole/ammonium polyacrylate and water is disclosed (see, for instance, Japanese Patent Application Laid-Open (JP-A) No. 2001-127019). According to the polishing processes described in these documents, a metal film of a convex portion of a semiconductor substrate is selectively subjected to the CMP and a metal film of a concave portion is left to form a desired conductor pattern. Since the CMP advances due to friction with a polishing pad that is mechanically far softer than a conventional one that contains abrasive grains, generation of scratches could be reduced, however, there is a problem in that a sufficient polishing speed is difficult to obtain.

As wiring metals, so far, tungsten and aluminum have been generally used in the interconnect structure. However, in order to achieve higher performance, LSIs that use copper which is lower in wiring resistance than these metals have been developed. As a process for wiring copper, for instance, a damascene process disclosed in JP-A No. 2-278822 is known. Furthermore, a dual damascene process where a contact hole and a wiring groove are simultaneously formed in an interlayer insulating film and a metal is buried in both is in wide use. As a target material for such copper wiring, a copper target having high purity of five ninths or more has been used. However, recently, as the wirings are miniaturized to carry out further densification, the conductivity and electric characteristics of the copper wiring require improvement; accordingly, a copper alloy where a third component is added to high-purity copper is under study. Simultaneously, a high-performance metal-polishing means that can exert high productivity without contaminating the high-precision and high-purity material is in demand.

Furthermore, recently, in order to improve the productivity, a wafer diameter when LSIs are produced is enlarged. At present, a diameter of 200 mm or more is generally used, and production at a magnitude of 300 mm or more as well has been started. As the wafer diameter is made larger like this, a difference in polishing speeds at a center portion and a periphery portion of the wafer tends to occur; accordingly, achievement of uniformity in the polishing is becoming important.

As a chemical polishing process that does not apply mechanical polishing means to copper and a copper alloy, a process that makes use of a chemical solvent action is known (see, for instance, JP-A No. 49-122432). However, in the chemical polishing process that depends only on the chemical solvent action, in comparison with the CMP where a metal film of a convex portion is selectively chemomechanically polished, a concave portion is polished, that is, dishing is caused; accordingly, a large problem remains with respect to the planarity.

On the other hand, though the polishing agent containing abrasive grains enables high polishing speed, it has the problem that dishing develops. Accordingly, there have been proposed a polishing liquid containing a specific organic acid (see, for example, JP-A No. 2000-183004) and an organic acid structure used appropriately in a polishing liquid capable of restraining dishing (see, for example, Japanese Patent Application National Phase Publication No. 2006-179845) for achieving a high polishing speed without increasing the amount of abrasive grains, but even the use of any such organic acid giving a high polishing speed and a passive film forming agent capable of restraining dishing has been unable to restrain dishing satisfactorily after the primary polishing process for copper and defects have been likely to occur from the corrosion of copper.

### SUMMARY

The present inventions have been made in view of the above circumstances and provide a metal-polishing liquid and a metal polishing method.

A first aspect of the invention provides a metal-polishing liquid used for chemical and mechanical polishing of copper wiring in a semiconductor device, the metal-polishing liquid comprising: (a) a tetrazole compound having a substituent in the 5-position; (b) a tetrazole compound not substituted in the 5-position; (c) abrasive grains; and (d) an oxidizing agent.

### DETAILED DESCRIPTION

After intensive studies under the circumstances above, the inventors have found that it was possible to solve the problems above by using together two kinds of nitrogen-containing heterocyclic compounds capable of restraining the melting of copper, and completed the invention.

Hereinafter, specific embodiments of the invention will be described.

### [Metal-Polishing Liquid]

The metal-polishing liquid according to the present invention comprises (a) a tetrazole compound having a substituent in the 5-position, (b) a tetrazole compound not substituted in the 5-position, (c) abrasive grains and (d) an oxidizing agent.

Description will now be made in detail of the metal-polishing liquid according to the present invention, though the following description is not intended for limiting the present invention.

A metal-polishing liquid according to the present invention is constituted by containing the components (a) to (d) above as essential constituents and usually contains water, etc., as well. The metal-polishing liquid according to the present invention may further contain other constituents as required. Preferred examples of the other constituents include an organic acid, a surfactant and/or a hydrophilic polymer, an acid, an alkaline agent and a buffering agent. The respective constituents which the liquid may contain (essential constituents and optional constituents) may be used alone or in combination of at least two kinds thereof.

In the invention, the “metal-polishing liquid” includes not only a polishing liquid used in the polishing (namely, a polishing liquid diluted as needed) but also a concentrated liquid of the metal-polishing liquid.

The concentrated liquid of the metal-polishing liquid means a liquid that is prepared higher in a concentration of a solute than a polishing liquid when used in the polishing and is used in the polishing after dilution with water or an aqueous solution. The dilution factor is generally in the range of 1 to 20 times by volume.

In the specification of the invention, the term “concentration” and “concentrated liquid” are used in accordance with follow conventional expressions that mean a higher “concentration” and a more “concentrated liquid” compared with a usage state and are used in a manner that differs in meaning from a general terminology that accompanies a physical concentrate operation such as vaporization.

Hereinafter, the respective constituents contained in a metal-polishing liquid of the invention will be described. First, the respective components (a), (b), (c) and (d) that are essential components in the metal-polishing liquid of the invention will be sequentially described.

### <(a) Tetrazole Compound Having a Substituent in the 5-Position>

The metal-polishing liquid according to the present invention contains (a) a tetrazole compound having a substituent in the 5-position (hereinafter referred to occasionally as “Specified compound A”).

The tetrazole compound (a) having a substituent in the 5-position is preferably a compound represented by Formula A below.

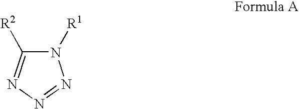

In Formula A, R¹ represents a hydrogen atom or an alkyl, aryl, alkoxy, amino, aminoalkyl, hydroxy, hydroxyalkyl, carboxy, carboxyalkyl or carbamoyl group, and when R¹ represents any substituent group other than a hydrogen atom, that group may further have a substituent group introduced into it. Examples of the substituent groups which can be introduced include alkyl, phenyl, hydroxy, carboxy, sulfo, carbamoyl, amide, amino and methoxy groups.

In Formula A, R² represents an alkyl, aryl, alkoxy, amino, aminoalkyl, hydroxy, hydroxyalkyl, carboxy, carboxyalkyl or carbamoyl group, and any such substituent group may further have a substituent group which can be introduced thereinto. Examples of the substituent groups which can be introduced include alkyl, phenyl, hydroxy, carboxy, sulfo, carbamoyl, amide, amino and methoxy groups.

The following are preferred examples of specified compounds represented by Formula A:
1H-tetrazole-5-acetic acid
1 H-tetrazole-5-carboxylic acid
1H-tetrazole-5-propionic acid
1H-tetrazole-5-sulfonic acid
1H-tetrazole-5-ol
1H-tetrazole-5 -carboxamide
1H-tetrazole-5-carboxamic acid
5-methyl-1H-tetrazole
5-ethyl-1H-tetrazole
5-n-propyl-1H-tetrazole
5-isopropyl-1H-tetrazole
5-n-butyl-1H-tetrazole
5-t-butyl-1H-tetrazole
5-n-pentyl-1H-tetrazole
5-n-hexyl-1H-tetrazole
5-phenyl-1H-tetrazole
5-amino-1H-tetrazole
5-aminomethyl-1H-tetrazole
5-aminoethyl-1H-tetrazole
5-(3-aminopropyl)-1H-tetrazole
5-ethyl-1-methyl-tetrazole
5-methanol-1H-tetrazole
5-(1-ethanol)-1H-tetrazole
5-(2-ethanol)-1H-tetrazole
5-(3-propane-1-ol)-1H-tetrazole
5-(1-propane-2-ol)-1H-tetrazole
5-(2-propane-2-ol)-1H-tetrazole
5 -(1-butane-1-ol)-1H-tetrazole
5-(1-hexane-1-ol)-1H-tetrazole
5-(1-cyclohexanol)-1H-tetrazole
5-(4-methyl-2-pentane-2-ol)-1H-tetrazole
5-methoxymethyl-1H-tetrazole
5-acetyl-1H-tetrazole
5-benzylsulfonyl-1H-tetrazole
5-dihydroxymethyl-1H-tetrazole
1-amino-5-n-propyl-tetrazole
1-amino-5-methyl-tetrazole

Among these, 5-amino-1H-tetrazole, 5-methyl-1H-tetrazole, 5-phenyl-1H-tetrazole, 5-ethyl-1-methyl-tetrazole, etc. are preferred, and 5-methyl-1H-tetrazole and 5-amino-1H-tetrazole are particularly preferred.

The metal-polishing liquid may contain only one compound represented by Formula A, or a combination of two or more.

The amount of (a) Specified Compound A which the metal-polishing liquid contains is preferably from 0.0001 to 0.1% by mass, more preferably from 0.001 to 0.05% by mass and still more preferably from 0.001 to 0.02% by mass, in consideration of polishing speed.

### <(b) Tetrazole Compound Not Substituted in the 5-Position>

The metal-polishing liquid according to the present invention contains (b) a tetrazole compound not substituted in the 5-position (hereinafter referred to occasionally as “Specified Compound B”).

The tetrazole compound (b) not substituted in the 5-position is preferably a compound represented by Formula B below.

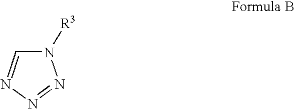

In Formula B, R³ represents a hydrogen atom or an alkyl, aryl, alkoxy, amino, aminoalkyl, hydroxy, hydroxyalkyl, carboxy, carboxyalkyl or carbamoyl group, and when R³ represents any substituent group other than a hydrogen atom, that group may further have a substituent group introduced into it. Examples of the substituent groups which can be introduced include alkyl, phenyl, hydroxy, carboxy, sulfo, carbamoyl, amide, amino and methoxy groups.

The following are preferred examples of specified compounds represented by Formula B:
1H-tetrazole(1,2,3,4-tetrazole)
1-aminoethyl-tetrazole
1-methanol-tetrazole
1-ethanol-tetrazole
1-(3-aminopropyl)-tetrazole
1-(β-aminoethyl)-tetrazole
1-methyl-tetrazole
1-acetic acid-tetrazole
1-amino-tetrazole

The metal-polishing liquid may contain only one compound represented by Formula B, or a combination of two or more.

The amount of (b) Specified compound B which the metal-polishing liquid contains is preferably from 0.0001 to 0.1% by mass, more preferably from 0.001 to 0.05% by mass and still more preferably from 0.001 to 0.02% by mass, in consideration of polishing speed.

The mass ratio of (a) Specified compound A and (b) Specified compound B in the metal-polishing liquid according to the present invention is preferably from 10:1 to 1:10, more preferably from 5:1 to 1:5 and still more preferably from 2:1 to 1:2. Observing these ranges results in a metal-polishing liquid which can prevent defects caused by the corrosion of copper.

### <(c) Abrasive Grains>

The metal-polishing liquid according to the present invention contains abrasive grains. Preferred examples of abrasive grains include silica (precipitated, fumed, colloidal or synthetic), ceria, alumina, titania, zirconia, germania and manganese oxide; among these, colloidal silica is preferred.

Colloidal silica particles preferred as abrasive grains may be prepared by, for example, the hydrolysis of a silicon alkoxide compound such as Si(OC₂H₅)₄, Si(sec-OC₄H₉)₄, Si(OCH₃)₄ or Si(OC₄H₉)₄ by the sol-gel method. The colloidal silica particles thereby prepared have a very sharp particle size distribution.

The primary particle diameter of abrasive grains means a particle diameter at a point where the cumulative frequency is 50% in the particle diameter cumulative frequency curve showing the relation between the particle diameter of abrasive grains and the cumulative frequency, obtained by integrating the number of particles with each particle diameter. As a measurement unit for obtaining a particle size distribution curve, for example, an analyzer LB-500 (trade name, produced by HORIBA Limited) may be used.

When the abrasive grains are spherical, the measured diameters may be used as they are, but when the abrasive grains have an irregular shape, it is necessary to employ the diameter of a sphere which would be equal in volume to the grains. While the particle size can be measured by any of various known methods, such as photon correlation methods, laser diffractometry and methods employing a Coulter counter, the present invention uses observations through a scanning microscope, or a replica method of taking photographs through a transmission electron microscope, for determining the shapes and sizes of the individual particles. More specifically, the area of the projection of particles with reference to a diffraction lattice having a known length is determined and the particle thickness is determined from the shadow of a replica, and the volume of the individual particles is calculated therefrom. It is desirable to measure 500 or more particles and process the results statistically, though this number may vary depending on the particle size distribution. This method is described in detail in Paragraph [0024] of JP-A-No. 2001-75222, and the description therein may be applied to the present invention.

The abrasive grains contained in the metal-polishing liquid according to the present invention preferably have an average (primary) particle diameter of from 20 to 70 nm and more preferably from 20 to 50 nm. A particle diameter of 5 nm or above is preferred for achieving a satisfactorily high polishing speed. A particle diameter of 50 nm or less is preferred for avoiding the generation of any excessive frictional heat during a polishing process.

It is possible to use organic polymer particles in a combination with the above described general inorganic abrasive grains, as long as the effect of the invention is not impaired. It is also possible to employ colloidal silica subjected to various kinds of surface treatment, such as having its surface modified with aluminate or borate ions or having its surface electric potential controlled, or to employ composite abrasive grains formed from a plurality of kinds of materials, depending on application.

While the amount of (c) abrasive grains which the metal-polishing liquid according to the present invention may contain depends on the application, it is generally from 0.001% to 20% by mass with respect to the total mass of the metal-polishing liquid, it is preferably less than 2.0% by mass, and more preferably from 0.01% to 1.0% by mass.

### <(d) Oxidizing Agent>

The metalpolishing liquid according to the invention contains a compound that oxidize the metal favorably to be polished (an oxidizing agent).

Examples of the oxidizing agents include hydrogen peroxide, peroxides, nitrate salts, iodate salts, periodate salts, hypochlorite salts, chlorite salts, chlorate salts, perchlorate salts, persulfate acid salts, dichromate salts, permanganate salts, ozone water, silver (II) salts, and iron (III) salts.

Favorable examples of the iron (III) salts include inorganic iron (III) salts such as iron nitrate (III), iron chloride (III), iron sulfate (III), and iron bromide (III), and organic iron (III) complex salts.

When an organic iron (III) complex salt is used, examples of the complex-forming compounds for the iron (III) complex salt include acetic acid, citric acid, oxalic acid, salicylic acid, diethyldithiocarbaminc acid, succinic acid, tartaric acid, glycolic acid, glycine, alanine, aspartic acid, thioglycol acid, ethylenediamine, trimethylenediamine, diethylene glycol, triethylene glycol, 1,2-ethanedithiol, malonic acid, glutaric acid, 3-hydroxybutyric acid, propionic acid, phthalic acid, isophthalic acid, 3-hydroxysalicylic acid, 3,5-dihydroxysalicylic acid, gallic acid, benzoic acid, maleic acid, the salts thereof, and aminopolycarboxylic acids and the salts thereof.

Examples of the amino polycarboxylic acid and the salts thereof include ethylenediamine-N,N,N′,N′-tetraacetic acid, diethylenetriaminepentaacetic acid, 1,3-diaminopropane-N,N,N′,N′-tetraacetic acid, 1,2-diaminopropane-N,N,N′,N′-tetraacetic acid, ethylenediamine-N,N′-disuccinic acid (racemic body), ethylenediaminedisuccinic acid (SS isomer), N-(2-carboxylatoethyl)-L-aspartic acid, N-(carboxymethyl)-L-aspartic acid, β-alaninediacetic acid, methyliminodiacetic acid, nitrilotriacetic acid, cyclohexanediaminetetraacetic acid, iminodiacetic acid, glycol ether diamine-tetraacetic acid, ethylenediamine-1-N,N′-diacetic acid, ethylenediamine-ortho-hydroxyphenylacetic acid, N,N-bis(2-hydroxybenzyl)ethylenediamine-N,N-diacetic acid, and the like, and the salts thereof. The counter salt is preferably an alkali-metal salt or an ammonium salt, particularly preferably an ammonium salt.

In particular, hydrogen peroxide, iodate salts, hypochlorite salts, chlorate salts, persulfate salts, and organic iron (III) complex salts are preferable; when an organic iron (III) organic complex salt is used, favorable complex-forming compounds include citric acid, tartaric acid, aminopolycarboxylic acid (specifically, ethylenediamine-N,N,N′,N′-tetraacetic acid, diethylenetriamine pentaacetic acid, 1,3-diaminopropane-N,N,N′,N′-tetraacetic acid, ethylenediamine-N,N′-disuccinic acid (racemic body), ethylenediamine disuccinic acid (SS isomer), N-(2-carboxylatoethyl)-L-aspartic acid, N-(carboxymethyl)-L-aspartic acid, β-alanine diacetic acid, methyliminodiacetic acid, nitrilotriacetic acid, and iminodiacetic acid).

Among the oxidizing agents above, hydrogen peroxide, persulfate salts, and iron (III) ethylenediamine-N,N,N′,N′-tetraacetate, and the complexes of 1,3-diaminopropane-N,N,N′,N′-tetraacetic acid and ethylenediaminedisuccinic acid (SS isomer) are most favorable.

The additive amount of the oxidizing agent (d) is preferably 0.003 mol to 8 mol, more preferably 0.03 mol to 6 mol, and particularly more preferably 0.1 mol to 4 mol, per L of the polishing composition used for polishing. The additive amount of the oxidizing agent is preferably 0.003 mol or more for assuring a CMP rate oxidizing the metal sufficiently and 8 mol or less for prevention of roughening of the polishing face.

The oxidizing agent is preferably used by mixing to a composition containing other components than the oxidant when a polishing liquid is used to polish. A timing when the oxidizing agent is mixed is preferably within 1 hr immediately before the polishing liquid is used, more preferably within 5 min, and particularly preferably within 5 sec immediately before feeding, after disposing a mixer immediate before the polishing liquid is fed in a polishing machine, on a surface to be polished.

The metal-polishing liquid according to the present invention may contain any of the following constituents, if required, in addition to the foregoing. The following is a description of the optional constituents which the metal-polishing liquid according to the present invention may contain.

—(e) Surfactant and/or Hydrophilic Polymer—

The metal-polishing liquid of the invention preferably contains a surfactant and/or a hydrophilic polymer (e). Both the surfactant and the hydrophilic polymer have an action to reduce the contact angle on the polishing face and to facilitate uniform polishing.

The surfactant and/or hydrophilic polymer (e) is preferably in the acid type, and, if it is in the salt structure, it is preferably a ammonium salt, potassium salt, sodium salt, or the like, particularly preferably an ammonium or potassium salt.

Anionic surfactants include carboxylate salts, sulfonate salts, sulfate ester salts, and phosphate ester salts: carboxylate salts including soaps, N-acylamino acid salts, polyoxyethylene or polyoxypropylene alkylether carboxylate salts, and acylated peptides; sulfonate salts including alkylsulfonate salts, alkylbenzene and alkylnaphthalenesulfonate salts, naphthalenesulfonate salts, sulfoscuccinate salts, a-olefin sulfonate salts, and N-acyl sulfonate salts; sulfate ester salts including sulfated oils, alkyl sulfate salts, alkylether sulfate salts, polyoxyethylene or polyoxypropylene alkylallylether sulfate salts, and alkyl amide sulfate salts; and phosphate ester salts including alkylphosphate salts and polyoxyethylene or polyoxypropylene alkylallylether phosphate salts.

Cationic surfactants include aliphatic amine salts, aliphatic quaternary ammonium salts, benzalkonium chloride salt, benzethonium chloride, pyridinium salts, and imidazolinium salts; and amphoteric surfactants include carboxybetaine-type, sulfobetaine type, aminocarboxylate salts, imidazolinium betaines, lecithins, and alkylamine oxides.

Nonionic surfactants include ether-type, ether ester-type, ester-type, nitrogen-containing-type; ether-type surfactants including polyoxyethylene alkyl and alkylphenylethers, alkyl allyl formaldehyde-condensed polyoxyethylene ethers, polyoxyethylene polyoxypropylene block polymer, and polyoxyethylene polyoxypropylene alkylethers; ether ester-type surfactants including glycerin ester polyoxyethylene ether, sorbitan ester polyoxyethylene ether, and sorbitol ester polyoxyethylene ether; ester-type surfactants including polyethylene glycol fatty acid esters, glycerin esters, polyglycerin esters, sorbitan esters, propylene glycol esters, and sucrose esters; nitrogen-containing surfactants including fatty acid alkanol amides, polyoxyethylene fatty acid amides, and polyoxyethylene alkyl amides; and the like.

In addition, fluorochemical surfactants and others are also included.

Furthermore, example of other surfactants, hydrophilic compounds and hydrophilic polymers include esters such as glycerin esters, sorbitan esters, methoxy-acetic acid, ethoxy-acetic acid, 3-ethoxy-propionic acid and alanine ethyl ester; ethers such as polyethylene glycol, polypropylene glycol, polytetramethylene glycol, polyethylene glycol alkyl ethers, polyethylene glycol alkenyl ethers, alkyl polyethylene glycols, alkyl polyethylene glycol alkyl ethers, alkyl polyethylene glycol alkenyl ethers, alkenyl polyethylene glycols, alkenyl polyethylene glycol alkyl ethers, alkenyl polyethylene glycol alkenyl ethers, polypropylene glycol alkyl ethers, polypropylene glycol alkenyl ethers, alkyl polypropylene glycols, alkyl polypropylene glycol alkyl ethers, alkyl polypropylene glycol alkenyl ethers, alkenyl polypropylene glycols, alkenyl polypropylene glycol alkyl ethers and alkenyl polypropylene glycol alkenyl ethers; polysaccharides such as alginic acid, pectic acid, carboxymethyl cellulose, curdlan and pullulan; amino acid salts such as ammonium salt of glycine and sodium salt of glycine; polycarboxylic acids and salts thereof such as polyaspartic acid, polyglutamic acid, polylysine, polymalic acid, polymethacrylic acid, ammonium salt of polymethacrylic acid, sodium salt of polymethacrylic acid, polyamide acids, polymaleic acid, polyitaconic acid, polyfumaric acid, poly(p-styrene carboxylic acid), polyacrylic acid, polyacrylamide, amino polyacrylamide, ammonium salt of polyacrylic acid, sodium salt of polyacrylic acid, polyamido acid, ammonium salt of polyamido acid, sodium salt of polyamido acid and polyglyoxylic acid; vinylic polymers such as polyvinyl alcohol, polyvinyl pyrrolidone and polyacrolein; sulfonic acids and salts thereof such as ammonium salt of methyl taurine acid, sodium salt of methyl taurine acid, sodium salt of methyl sulfate, ammonium salt of ethyl sulfate, ammonium salt of butyl sulfate, sodium salt of vinyl sulfonate, sodium salt of 1-allyl sulfonate, sodium salt of 2-allyl sulfonate, sodium salt of methoxy-methyl sulfonate, ammonium salt of ethoxy-methyl sulfonate, sodium salt of 3-ethoxy-propyl sulfonate, sodium salt of methoxy-methyl sulfonate, ammonium salt of ethoxy-methyl sulfonate, sodium salt of 3-ethoxy-propyl sulfonate and sodium sulfo-succinate; and amides such as propionamide, acrylamide, methyl urea, nicotinamide, succinic acid amide and sulfanilamide.

However, when the base substance to be processed is for example a silicon substrate for semiconductor integrated circuit, contamination with an alkali metal, alkali-earth metal, or halide is undesirable, thus, the foregoing additives are desirably acids and ammonium salts thereof. The surfactant is arbitrary, if the base substance is for example glass. Among the exemplary compounds above, ammonium salt of polyacrylic acid, polyvinyl alcohol, succinic acid amide, polyvinyl pyrrolidone, polyethylene glycol, polyoxyethylene polyoxy-propylene block polymer are more preferable.

The amount of (e) surfactant which the metal-polishing liquid may contain is preferably from 0.0001 g to 1 g, more preferably from 0.001 g to 0.5 g, and still more preferably from 0.01 g to 0.3 g, in total per liter of the liquid which is used for polishing. In other words, the amount of the surfactant is preferably not smaller than 0.0001 g in order to be sufficiently effective, and not larger than 1 g to avoid a reduction of the CMP speed.

The surfactant preferably has a weight-average molecular weight of from 500 to 100,000 and more preferably from 2,000 to 50,000.

It is possible to use a single kind of surfactant alone or two or more different kinds of agents together.

### <Organic Acid>

The metal-polishing liquid according to the present invention preferably contains an organic acid. The organic acid promotes the elution of copper. The organic acid may be selected from amino, acetic, butyric or other organic acids, or salts thereof.

Examples of the amino acids include glycine, L-alanine, β-alanine, L-2-aminobutyric acid, L-norvaline, L-valine, L-leucine, L-norleucine, L-isoleucine, L-alloisoleucine, L-phenylalanine, L-proline, sarcosine, L-ornithine, L-lysine, taurine, L-serine, L-threonine, L-allothreonine, L-homoserine, L-tyrosine, 3,5-diiodo-L-tyrosine, L-thyroxine, L-cycteine, L-methionine, L-ethionine, L-lanthionine, L-cystathionine, L-cystine, L-cysteine acid, L-aspartic acid, L-glutamic acid, S-(carboxymethyl)-L-cysteine, 4-aminobutyric acid, L-asparagine, L-glutamine, azaserine, L-arginine, L-canabanine, L-citrulline, creatine, L-kinurenine, L-histidine, 1-methyl-L-histidine, 3-methyl-L-histidine, ergothioneine, L-triptophane, actinomycine C1, apamine, angiotensin I, angiotensin II and antipaine.

Other examples are the amino acids having hydroxy-ethyl group specified in Japanese Patent Application 2006-269410.

Examples of the organic acids other than amino acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, hydroxyethyliminodiacetic acid and iminodiacetic acid and their salts including ammonium and alkali metal salts.

Among these, glycine, L-alanine, sarcosine, L-aspartic acid, L-asparagine, L-glutamic acid and L-glutamine are preferred in consideration of polishing speed.

The amount of the organic acid which the metal-polishing liquid according to the present invention may contain is preferably from 0.001 to 1.0 mol, more preferably from 0.01 to 0.5 mol and still more preferably from 0.05 to 0.3 mol per liter of the liquid which is used for polishing. In other words, the amount of the organic acid is preferably not smaller than 0.001 mol to be fully effective, and not larger than 1.0 mol to restrain etching.

The metal-polishing liquid according to the present invention may contain an inorganic acid so that it may, for example, serve as an oxidation promoter, a pH adjuster, or a buffering agent.

Any inorganic acid, such as sulfuric, nitric or boric acid, can be employed without any particular limitation. Nitric acid is, however, preferred.

### <Passive Film Forming Agent>

The metal-polishing liquid according to the present invention may contain a common passive film forming agent to an extent not impairing the effects of the invention, added to (a) Specified compound A and (b) Specified compound B as described above.

The passive film forming agent is a compound such as a heterocyclic compound which can form a passive film controlling the polishing speed on the metal surface to be polished. The heterocyclic compound has the function of restraining the decomposition caused by an oxidizing agent in addition to the function of forming a passive film.

Here, the “heterocyclic compound” is a compound having a heterocycle containing at least one hetero atom. The “hetero atom” means an atom other than a carbon atom and a hydrogen atom. The heterocycle means a ring compound having at least one hetero atom. The hetero atom means only an atom that constitutes a constituent portion of a ring system of the heterocycle but not an atom located outside of the ring system, nor an atom separated from the ring system via at least one non-conjugate single bond, and nor an atom that is a part of a further substituent of the ring system.

Preferable examples of the hetero atoms include a nitrogen atom, a sulfur atom, an oxygen atom, a selenium atom, a tellurium atom, a phosphorus atom, a silicon atom and a boron atom. More preferable examples thereof include a nitrogen atom, a sulfur atom, an oxygen atom and a selenium atom. Particularly preferable examples thereof include a nitrogen atom, a sulfur atom and an oxygen atom. Most preferable examples thereof include a nitrogen atom and a sulfur atom.

The heterocyclic compound that may be employed by the present invention preferably has four or more hetero atoms, more preferably three or more nitrogen atoms and still more preferably four or more nitrogen atoms.

The heterocyclic compound which may be employed by the present invention is not specifically limited in the number of members of its heterocyclic rings, but may be a monocyclic compound or a polycyclic compound having a condensed ring.

The monocyclic compound preferably has five to seven and more preferably five ring members. The polycyclic compound preferably has two or three rings.

Specific examples of the preferred heterocyclic rings include imidazole, pyrazole, triazole, tetrazole, benzimidazole, benzoxazole, naphthoimidazole, benztriazole and tetraazaindene rings, and more preferably triazole and tetrazole rings, but not specifically limited thereto.

Examples of the substituent groups which can be introduced into heterocyclic compounds are a halogen atom and an alkyl, alkenyl, alkinyl, aryl, amino or heterocyclic group.

Two or more of a plurality of substituent groups may combine with each other to form a ring, for example, an aromatic, aliphatic hydrocarbon, or heterocyclic ring.

Specific examples of the heterocyclic compounds which are preferably employed for the present invention are 1,2,3-triazole, 4-amino-1,2,3-triazole, 4,5-diamino-1,2,3-triazole, 1,2,4-triazole, 3-amino-1,2,4-triazole, 3,5-diamino-1,2,4-triazole, benzotriazole and 5-aminobenzo-triazole.

It is acceptable to use only a single heterocyclic compound, or it is possible to use two or more together. The heterocyclic compounds may be synthesized by an ordinary method, or may be chosen from commercially available products.

The amount of the heterocyclic compound which the metal-polishing liquid according to the present invention may contain is preferably from 0.0001 to 0.1 mol, more preferably from 0.0003 to 0.05 mol and still more preferably from 0.0005 to 0.01 mol in total of [(a) Specified compound A, (b) Specified compound B, and any other optional heterocyclic compound] per liter of the liquid which is used for polishing.

(Alkali Agent/Buffering Agent)

Furthermore, the metal-polishing liquid of the invention, as needed, may contain an alkali agent for adjusting the pH and a buffering agent from the viewpoint of inhibiting the pH from fluctuating.

Examples of such alkaline agents and buffering agents include non-metallic alkali agents such as organic ammonium hydroxide such as ammonium hydroxide and tetramethyl-ammonium hydroxide, and alkanol-amines such as diethanolamine, triethanolamine and tri-isopropanol-amine; alkali metal hydroxides such as sodium hydroxide, potassium hydroxide, and lithium hydroxide; carbonates, phosphates, borates, tetraborates, hydroxy-benzoate, glycylates, N,N-dimethyl glycylates, leucine salts, norleucine salts, guanine salts, 3,4-dihydroxy-phenylalanine salts, alanine salts, amino-butyl lactate, 2-amino-2-methyl-1,3-propanediol salts, valine salts, proline salts, tris(hydroxy)amino-methane salts and lysine salts.

Specific examples of such alkaline agents and buffering agents include sodium hydroxide, potassium hydroxide, lithium hydroxide, sodium carbonate, potassium carbonate, sodium bicarbonate, potassium bicarbonate, tri-sodium phosphate, tri-potassium phosphate, di-sodium phosphate, di-potassium phosphate, sodium borate, potassium borate, sodium tetraborate (borax), potassium tetraborate, sodium o-hydroxy-benzoate (sodium salicylate), potassium o-hydroxy-benzoate, sodium 5-sulfo-2-hydroxy-benzoate (sodium 5-sulfosalicylate), potassium 5-sulfo-2-hydroxy-benzoate (potassium 5-sulfosalicylate), and ammonium hydroxide.

Particularly preferable examples of the alkaline agents include ammonium hydroxide, potassium hydroxide, lithium hydroxide and tetramethyl-ammonium hydroxide.

Addition amounts of the alkaline agents and buffering agents are not particularly limited as long as pH may be maintained in a preferable range, and this is preferably in the range of 0.0001 to 1.0 mol and more preferably in the range of 0.003 to 0.5 mol with respect to 1 L of the polishing liquid used in the polishing.

### —Chelating Agent—

In the metal-polishing liquid of the invention, in order to reduce an adverse effect of mingling polyvalent metal ions, as needed, a chelating agent (that is, a water softener) is preferably contained.

Such a chelating agent may be general-purpose water softeners serving as a precipitation inhibitor of calcium or magnesium or analogous compounds thereof, and specific examples thereof include nitrilotriacetic acid, diethylene-triamine-pentaacetic acid, ethylenediamine-tetraacetic acid, N,N,N-trimethylene-phosphonic acid, ethylenediamine-N,N,N′,N′-tetramethylene-sulfonic acid, trans-cyclohexane-diamine-tetraacetic acid, 1,2-diamino-propane-tetraacetic acid, glycol ether diamine-tetraacetic acid, ethylenediamine-o-hydroxy-phenyl acetic acid, ethylenediamine disuccinic acid (SS isomer), N-(2-carboxylate ethyl)-L-aspartic acid, β-alanine diacetic acid, 2-phosphonobutane-1,2,4-tricarboxylic acid, 1-hydroxy-ethylidene-1,1-diphosphonic acid, N,N′-bis(2-hydroxybenzyl)ethylenediamine-N,N′-diacetic acid and 1,2-dihydroxybenzene-4,6-disulfonic acid.

The chelating agents may be used alone or, as needed, in a combination of at least two of them.

An addition amount of the chelating agent may be an amount sufficient for sequestering metal ions such as contaminated polyvalent metal ions; accordingly, the chelating agent is added so as to be in the range of 0.003 to 0.07 mol in 1 L of the metal polishing liquid at the time of the polishing.

<Phosphate or phosphite>

The metal-polishing liquid according to the present invention preferably contains a phosphate or phosphite when it contains any inorganic constituent other than abrasive grains.

The constituents of the metal-polishing liquid according to the present invention, kinds and the amounts thereof and the pH are preferably selected by taking into consideration factors such as the reactivity and adsorbability of such constituents to the surface to be polished, the solubility of the metal to be polished, the electrochemical properties of the surface to be polished, the degree of dissociation of the functional groups in such constituent compounds, and the stability as a liquid.

The metal-polishing liquid according to the present invention preferably, in consideration of flattening performance, has a pH of from 3 to 10, more preferably from 3.8 to 9.0 and still more preferably from 6.0 to 8.0. The pH can be adjusted easily by such as by adding a buffering agent, an alkaline agent, or an inorganic acid.

The metal-polishing liquid according to the present invention preferably has a specific gravity of from 0.8 to 1.5 and more preferably from 0.95 to 1.35 in consideration of fluidity and polishing performance stability.

### [Materials of Wiring]

The semiconductor to be polished by the present invention is preferably an LSI having wiring connections formed from copper and/or a copper alloy, more preferably wiring connections formed from a copper alloy. The copper alloy preferably contains silver. The content of silver is preferably 40% by mass or less, more preferably 10% by mass or less and still more preferably 1% by mass or less. The present invention produces the best result on a copper alloy having a silver content of 0.00001 to 0.1% by mass.

### [Wire Thickness]

The semiconductor to be polished in accordance with the present invention preferably is an LSI which for instance has a half pitch of 0.15 μm or less, more preferably 0.10 μm or less and still more preferably 0.08 μm or less when it is a DRAM device, or has a half pitch of 0.12 μm or less, more preferably 0.09 μm or less and still more preferably 0.07 μm or less when it is an MPU device. The polishing liquid according to the present invention produces a particularly good result on such LSIs.

### [Metallic Barrier Material]

The semiconductor material to be polished in accordance with the present invention preferably has a barrier layer formed between copper and/or copper alloy wiring and an insulating film between layers for preventing the diffusion of copper. The barrier layer is preferably formed from a metallic material of low resistance, such as TiN, TiW, Ta, TaN, W, WN or Ru, and more preferably from Ta or TaN.

### [Polishing Method]

The metal-polishing liquid according to the present invention may be available in the form of a concentrated liquid for dilution with water to prepare a liquid ready for use, or in the form of a combination of aqueous solutions of its constituents, as will be described below, for mixing, and dilution with water as required, to prepare a liquid ready for use, or may be in the form of a liquid ready for use.

The polishing method according to the present invention is a method which may be carried out with any such form of liquid, and in which the polishing liquid is supplied to a polishing pad on a polishing platen and the surface to be polished is brought into contact with the polishing pad and moved relative to each other.

The polishing method may be carried out by employing a common polishing apparatus having a holder for holding a semiconductor substrate to be polished and a polishing platen (equipped with a motor having a variable rotating speed) having a polishing pad attached thereto.

A common non-woven fabric, polyurethane foam, or porous fluororesin may, for example, be used for the polishing pad, without any particular limitations.

While there is no specific limitation as to the polishing conditions, the polishing platen is preferably rotated at a low speed of 200 rpm or less so that the substrate to be polished does not fly off.

A pressure 20 kPa or less is preferably applied to press the semiconductor substrate having the surface (or film) to be polished against the polishing pad, and a pressure of 6 to 15 kPa is more preferable to ensure a uniform polishing speed all over the wafer surface and a satisfactory pattern flatness.

The metal-polishing liquid is continuously supplied to the polishing pad by a pump, etc. while polishing. While there is no specific limitation as to the amount of the liquid to be supplied, it is preferable to ensure that the polishing pad always have its surface covered with the liquid.

The semiconductor substrate which has been polished is rinsed carefully in flowing water, has water drops expelled by e.g. a spin dryer, and is allowed to dry. The metal-polishing liquid according to the present invention is easy to remove by rinsing from the polished substrate, apparently owing to an electrostatic repulsion between the abrasive grains and the metal of the wiring.

In the polishing method of the invention, an aqueous solution that is used to dilute the metal-polishing liquid is same as the aqueous solution described below. The aqueous solution is water previously containing at least one of an oxidizing agent, an acid, an additive and a surfactant, and a component obtained by sum totaling a component contained in the aqueous solution and a component in the metal-polishing liquid that is diluted serves as a component when the metal-polishing liquid is used to polish. When the metal-polishing liquid is diluted with an aqueous solution and used, a component that is difficult to dissolve can be compounded in the form of the aqueous solution; accordingly, a more concentrated metal-polishing liquid can be prepared.

As a method of adding water or an aqueous solution to a concentrated metal-polishing liquid to carry out diluting, there is a method where a pipe that feeds the concentrated metal-polishing liquid and a pipe that feeds water or an aqueous solution are flowed together on the way to carry out mixing and the mixed and diluted metal-polishing liquid is fed to a polishing pad. When the liquids are mixed, commonly applied methods such as a method where, under pressure, liquids are forced to flow through a narrow path to collide with each other to mix the liquids, a method where, in the pipe, a packing material such as glass tubes is filled, whereby a stream is repeatedly divided, separated and flowed together, or a method where a blade rotated by power is disposed in a pipe may be adopted.

The metal-polishing liquid may be supplied at a rate of 10 to 1,000 ml/min, but is preferably supplied at a rate 190 ml/min or less and more preferably from 100 to 190 ml/min in view of its physical properties.

According to one mode of the polishing method of the present invention employing a concentrated metal-polishing liquid diluted with an aqueous solution or the like, appropriate amounts of the metal-polishing liquid and of water, or an aqueous solution, are each supplied to the polishing pad through separate pipelines and mixed together by the relative motion of the pad and the surface to be polished.

According to another mode of the polishing method, certain amounts of a concentrated metal-polishing liquid and water are mixed in a single vessel and the mixture is then supplied to the polishing pad.

According to a further mode of the polishing method according to the present invention, the constituents forming the metal-polishing liquid are separated into at least two constituent groups, and when these are used, water is added to each of the constituents groups to dilute them, the diluted constituents are supplied to the polishing pad, and the polishing pad is brought into contact with the surface to be polished, so that polishing may be carried out by the relative motion of the surface to be polished and the polishing pad.

For example, the oxidizing agent is employed as one constituent group (A) and the acid, additives, surfactant and water are employed as another constituent group (B), and the constituent groups (A) and (B) are diluted with water before they are used.

It is also possible to divide the additives of low solubility into two groups of constituents (A) and (B), with the oxidizing agent, some additives and surfactant as one constituent group (A), and the acid, other additives, surfactant and water as the other constituent group (B), and dilute the constituent groups (A) and (B) with water before using them.

These arrangements require three pipelines, for supplying the constituent groups (A), (B) and water, respectively, and for mixing and dilution these three pipelines may be connected together with single pipeline leading to the polishing pad, thereby mixing these constituents and water together. When doing so it is possible to connect one of the three pipelines to the pipeline leading to the polishing pad after the other two have been connected.

For example, one method is to employ a long mixing route, thereby securing a long dissolving time for mixing constituents containing additives which are not easily dissolved with the other constituents, and then to connect the pipeline with water to this route to prepare the polishing liquid.

Other methods are to lead the three pipelines directly to the polishing pad and rely on the relative motion of the pad and the surface to be polished for mixing the two groups of constituents and water, or to mix the two groups of constituents and water in a single vessel and supply the diluted metal-polishing liquid therefrom to the polishing pad.

When any of the methods described above is carried out, it is possible to heat the one group of constituents including the oxidizing agent to a temperature of 40° C. or less and to heat the other group of constituents to a range from room temperature to 100° C., so that their mixture diluted with water may have a temperature of 40° C. or less when it is used.

This is a method which is desirable for raising the solubility of a material of low solubility in the metal-polishing liquid, since raising its temperature raises its solubility.

Since some materials dissolved by heating the constituent group not including the oxidizing agent to a range from room temperature to 100° C. may be precipitated in the solution with a drop in temperature, solutions containing such materials which have been lowered in temperature may have to be heated again to re-dissolve such materials before the constituents are used.

This may made possible by employing a unit for conveying a solution containing materials which dissolved with heat and an unit for stirring a solution containing the precipitated materials, conveying them and heating the conveying pipe to dissolve those materials.

As there is a concern that oxidizing agents may decompose when heated constituents raise the temperature of the other constituents including the oxidizing agent to 40° C. or higher, it is necessary to ensure that the mixture of the heated constituents and the constituents including the oxidizing agent, which cool the heated constituents, has a temperature of 40° C. or lower.

The present invention makes it possible to supply two or more groups of constituents forming the metal-polishing liquid separately to the surface to be polished, as stated above. One group of constituents preferably includes the oxidizing agent, while another includes the acid. It is also possible to employ a concentrated metal-polishing liquid, supplying it and diluting water separately to the surface to be polished.

### [Pad]

The polishing pad may be of the non-foamed or foamed type. The former is a pad formed from a hard synthetic resin bulk material, like a plastic sheet. The latter includes a closed-cell foam (dry foam), an interconnected-cell foam (wet foam) and a two-layer composite (laminate): of these, a two-layer composite (laminate) is preferred. The foam may be uniform or non-uniform.

The polishing pad may contain abrasive grains such as ceria, silica, alumina or a resin, used for polishing. The pad may be a soft or hard one and the laminate preferably has layers differing in hardness. The pad is preferably formed from e.g. a non-woven fabric, an artificial leather, polyamide, polyurethane, polyester or polycarbonate. It may have e.g. a grid of grooves, holes or concentric or spiral grooves formed in the surface which contacts the surface to be polished.

### [Wafer]

The wafer to be chemically and mechanically polished with the metal-polishing liquid according to the present invention preferably has a diameter of 200 mm or more and more preferably 300 mm or more. The present invention produces a particularly favorable result on a wafer having a diameter of 300 mm or more.

Modes of carrying out the present invention will now be set forth as examples.
<1> A metal-polishing liquid used for chemical and mechanical polishing of copper wiring in a semiconductor device, the metal-polishing liquid comprising: (a) a tetrazole compound having a substituent in the 5-position; (b) a tetrazole compound not substituted in the 5-position; (c) abrasive grains; and (d) an oxidizing agent.
<2> The metal-polishing liquid as set forth at <1> above, wherein the tetrazole compound having a substituent in the 5-position is a compound represented by Formula A below.

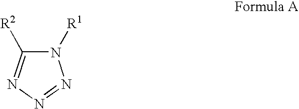

In Formula A; R¹ represents a hydrogen atom or an alkyl, aryl, alkoxy, amino, aminoalkyl, hydroxy, hydroxyalkyl, carboxy, carboxyalkyl or carbamoyl group; and R² represents an alkyl, aryl, alkoxy, amino, aminoalkyl, hydroxy, hydroxyalkyl, carboxy, carboxyalkyl or carbamoyl group.
<3> The metal-polishing liquid as set forth at <1> or <2> above, wherein the tetrazole compound not substituted in the 5-position is a compound represented by Formula B below.

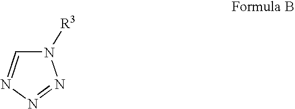

In Formula B, R³ represents a hydrogen atom or an alkyl, aryl, alkoxy, amino, aminoalkyl, hydroxy, hydroxyalkyl, carboxy, carboxyalkyl or carbamoyl group.
<4> The metal-polishing liquid as set forth at <2> above, wherein the compound represented by Formula A is at least one of the compounds selected from the group consisting of 5-amino-1H-tetrazole, 5-methyl-1H-tetrazole, 5-phenyl-1H-tetrazole, and 5-ethyl-1-methyl-tetrazole.
<5> The metal-polishing liquid as set forth at <2> or <4> above, wherein the compound represented by Formula A is 5-methyl-1H-tetrazole.
<6> The metal-polishing liquid as set forth at <3> above, wherein the compound represented by Formula B is at least one of the compounds selected from the group consisting of 1H-tetrazole, 1-acetic acid-tetrazole, 1-methyl-tetrazole and 1-(β-aminoethyl)-tetrazole.
<7> The metal-polishing liquid as set forth at any of <1> to <6> above, further comprising (e) a surfactant.
<8> A method for chemical and mechanical polishing of a semiconductor device in which a surface of the semiconductor device to be polished is polished by: supplying a metal-polishing liquid to a polishing pad and relatively moving the surface to be polished with respect to a polishing pad disposed on a polishing platen and brought into contact with the surface to be polished, wherein the metal-polishing liquid comprises (a) a tetrazole compound having a substituent in the 5-position, (b) a tetrazole compound not substituted in the 5-position, (c) abrasive grains and (d) an oxidizing agent.
<9> The method for chemical and mechanical polishing as set forth at <8> above, wherein a pressure of 20 kPa or less is applied to press the surface to be polished against the polishing pad during the relative motion thereof.
<10> The method for chemical and mechanical polishing as set forth at <8> or <9> above, wherein the metal-polishing liquid is supplied to the polishing pad at a rate of 190 ml/min or less.

### EXAMPLES

The present invention will now be described by examples, though these examples are not intended to limit the present invention.

### Example 1

### —Metal-Polishing Liquid—

(a) Compound represented by Formula A [a-1] (Amount shown in Table 2);
(b) Compound represented by Formula B [b-1] (Amount shown in Table 3);
(c) Abrasive grains [PL-3, trade name produced by FUSO Chemical Co., LTD.](Cocoon-shaped colloidal silica particles having a primary particle diameter of 35 nm) (0.5% by mass);

| | |
|---|---|
| (d) Oxidizing agent (30% hydrogen peroxide) | 20 ml/L |
| Glycine | 10 g/L |
| pH (adjusted to a pH of 7 with ammonia water). | |

### Examples 2 to 9

Metal-polishing liquids 2 to 9 were prepared in a similar manner as in Example 1 except that the compounds (a) and (b) used in Example 1 were changed to the components shown in Table 1. The metal-polishing liquid according to Example 8 was prepared by further employing 10 ppm of the anionic surfactant dodecylbenzenesulfonic acid (shown as “DBS” in Table 1) as component (e). Further, the metal-polishing liquid according to Example 9 was prepared by further employing 10 ppm of a condensation product of sodium naphthalenesulfonate and formalin (shown as “NSF” in Table 1), which is an anionic polymer, as component (e).

### Comparative Example 1

A metal-polishing liquid according to a Comparative Example 1 was prepared in a similar manner as in Example 1 except that (b) a compound represented by Formula B was not added to the liquid.

### Comparative Example 2

A metal-polishing liquid according to a Comparative Example 2 was prepared in a similar manner as in Example 2 except that (b) a compound represented by Formula B was not added to the liquid.

### Comparative Example 3

A metal-polishing liquid according to a Comparative Example 3 was prepared in a similar manner as in Example 3 except that (a) a compound represented by Formula A was not added to the liquid.

The metal-polishing liquids according to Examples 1 to 9 and Comparative Examples 1 to 3 were prepared and used for polishing according to the polishing method shown below to evaluate the polishing properties (polishing speed, dishing and corrosion). The results are shown in Table 1.

### <Evaluation for Polishing Speed>

As a polishing apparatus, an apparatus FREX-300 (trade name, produced by EBARA Corporation) was used to polish a film disposed on a wafer under the following conditions while slurry of the metal-polishing liquid was fed, and the polishing speed was calculated.
Substrate: 12-inch silicon wafer having a copper film formed thereon;
Table rotational frequency: 104 rpm;
Head rotational frequency: 105 rpm;
(Processing line velocity: 1.0 m/s);
Polishing pressure: 10.5 kPa;
Polishing pad: IC-1400 (trade name produced by ROHM & HAAS)
Slurry supply rate: 190 ml/min;

### Determination of Polishing Speed:

The thickness of the copper film was estimated from electrical resistance before its polishing and thereafter, and the polishing speed was calculated by the following equation:

Polishing speed (nmÅ/min)=(Thickness of copper film before polishing−Thickness of copper film after polishing)/Polishing time

### <Evaluation for Dishing>

By way of an apparatus, FREX-300 (trade name, produced by EBARA Corporation) as a polishing apparatus, a film disposed on a patterned wafer was polished under the following conditions while slurry was fed, and a step at that time was measured as shown below.
Substrate: 12-inch wafer having a patterned silicon oxide film in which wiring channels having a width of 0.09 to 100 μm and a depth of 600 nm and connecting holes were formed by photolithography and reactive ion etching, and on which a Ta film having a thickness of 20 nm was formed by sputtering, a copper film having a thickness of 50 nm was formed by sputtering, and a copper film having a total thickness of 1,000 nm was formed by plating.
Table rotational frequency: 50 rpm;
Head rotational frequency: 50 rpm;
Polishing pressure: 10.5 kPa;
Polishing pad: IC-1 400 (trade name produced by RODEL NITTA)
Slurry supply rate: 200 ml/min;

### Measurement of Step:

By use of a needle-contacting type profilometer, a step at L/S of 100 μm/100 μm was measured.

### <Evaluation for Corrosion >

Each wiring having a size of 100 μm on the polished surface was examined through an electron microscope S-4800 (trade name, produced by HITACH HIGH TECHNOLOGIES). The copper wiring surface was examined for corrosion and when no corrosion was found, the result is shown as “None” in Table 1.

Details of (a) Compounds represented by Formula A are shown in Table 2, and details of (a) Compounds represented by Formula B in Table 3.

TABLE 1

| | | (a) Compound | (b) Compound | | Polishing | | |
|---|---|---|---|---|---|---|---|
| | | represented by | represented by | | speed, | Dishing | |
| | Slurry | Formula A | Formula B | Surfactant | nm/min | nm | Corrosion |
| Example 1 | S-1 | a-1 | b-1 | | 458 | 31 | None |
| Example 2 | S-2 | a-2 | b-1 | | 493 | 25 | None |
| Example 3 | S-3 | a-3 | b-1 | | 384 | 35 | None |
| Example 4 | S-4 | a-4 | b-1 | | 426 | 38 | None |
| Example 5 | S-5 | a-1 | b-2 | | 465 | 34 | None |
| Example 6 | S-6 | a-1 | b-3 | | 437 | 39 | None |
| Example 7 | S-7 | a-1 | b-4 | | 394 | 37 | None |
| Example 8 | S-8 | a-1 | b-1 | DBS | 385 | 26 | None |
| | | | | 10 ppm | | | |
| Example 9 | S-9 | a-1 | b-1 | NSF | 358 | 28 | None |
| | | | | 10 ppm | | | |
| Comparative | S-10 | a-1 | | | 501 | 52 | None |
| Example 1 | | | | | | | |
| Comparative | S-11 | a-2 | | | 519 | 46 | Found |
| Example 2 | | | | | | | |
| Comparative | S-12 | | b-1 | | 527 | 62 | Found |
| Example 3 | | | | | | | |

TABLE 2

| | (a) Compound represented | |
|---|---|---|
| | by Formula A | Amount employed (ppm) |
| a-1 | 5-amino-1H-tetrazole | 55 |
| a-2 | 5-methyl-1H-tetrazole | 54 |
| a-3 | 5-phenyl-1H-tetrazole | 20 |
| a-4 | 5-ethyl-1-methyl-tetrazole | 20 |

TABLE 3

| | (b) Compound represented | |
|---|---|---|
| | by Formula B | Amount employed (ppm) |
| b-1 | 1,2,3,4-tetrazole | 45 |
| b-2 | 1-methyl-tetrazole | 54 |
| b-3 | 1-(β-aminoethyl)-tetrazole | 60 |
| b-4 | 1-acetic acid-tetrazole | 15 |

As is obvious from the results of Examples 1 to 9 shown in Table 1, the metal-polishing liquids of the present invention containing (a) compounds represented by Formula A and (b) compounds represented by Formula B ensures the control of dishing and corrosion, while maintaining a satisfactorily high polishing speed.

According to the present invention, there are provided a metal-polishing liquid which can effectively suppress dishing and any defect caused by the corrosion of copper, while permitting a high polishing speed, and a polishing method employing the same.

What is claimed is:

1. A metal-polishing liquid used for chemical and mechanical polishing of copper wiring in a semiconductor device, the metal-polishing liquid comprising: (a) a tetrazole compound having a substituent in the 5-position; (b) a tetrazole compound not substituted in the 5-position; (c) abrasive grains; and (d) an oxidizing agent.

2. The metal-polishing liquid according to claim 1, wherein the tetrazole compound having a substituent in the 5-position is a compound represented by Formula A: 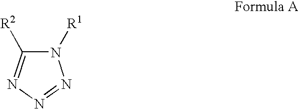
wherein, in Formula A: R¹ represents a hydrogen atom or an alkyl, aryl, alkoxy, amino, aminoalkyl, hydroxy, hydroxyalkyl, carboxy, carboxyalkyl or carbamoyl group; and R² represents an alkyl, aryl, alkoxy, amino, aminoalkyl, hydroxy, hydroxyalkyl, carboxy, carboxyalkyl or carbamoyl group.

3. The metal-polishing liquid according to claim 1, wherein the tetrazole compound not substituted in the 5-position is a compound represented by Formula B: 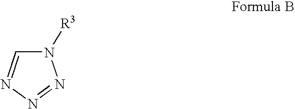
wherein, in Formula B, R³ represents a hydrogen atom or an alkyl, aryl, alkoxy, amino, aminoalkyl, hydroxy, hydroxyalkyl, carboxy, carboxyalkyl or carbamoyl group.

4. The metal-polishing liquid according to claim 2, wherein the compound represented by Formula A is at least one compound selected from the group consisting of 5-amino-1H-tetrazole, 5-methyl-1H-tetrazole, 5-phenyl-1H-tetrazole, and 5-ethyl-1-methyl-tetrazole.

5. The metal-polishing liquid according to claim 2, wherein the compound represented by Formula A is 5-methyl-1H-tetrazole.

6. The metal-polishing liquid according to claim 3, wherein the compound represented by Formula B is at least one compound selected from the group consisting of 1H-tetrazole, 1-acetic acid-tetrazole, 1-methyl-tetrazole and 1-(β-aminoethyl)-tetrazole.

7. The metal-polishing liquid according to claim 1, further comprising (e) a surfactant.

8. A method for chemical and mechanical polishing of a semiconductor device in which the surface of a semiconductor device to be polished is polished by:
supplying a metal-polishing liquid to a polishing pad and relatively moving the surface to be polished with respect to a polishing pad disposed on a polishing platen and brought into contact with the surface to be polished, wherein the metal-polishing liquid comprises (a) a tetrazole compound having a substituent in the 5-position, (b) a tetrazole compound not substituted in the 5-position, (c) abrasive grains and (d) an oxidizing agent.

9. The method for chemical and mechanical polishing according to claim 8, wherein a pressure of 20 kPa or less is applied to press the surface to be polished against the polishing pad during the relative motion thereof.

10. The method for chemical and mechanical polishing according to claim 8, wherein the metal-polishing liquid is supplied to the polishing pad at a rate of 190 ml/min or less.
